(19) United States
(12) Patent Application Publication
(10) Pub. No.: US 2025/0175173 A1
(43) Pub. Date: May 29, 2025

(54) CIRCUIT ARRANGEMENT FOR A TOPOLOGICAL SEMICONDUCTOR SWITCH OF AN INVERTER

(71) Applicant: ZF Friedrichshafen AG, Friedrichshafen (DE)

(72) Inventors: Teresa Bertelshofer, Bayreuth (DE); Michael Meiler, Bayreuth (DE)

(73) Assignee: ZF Friedrichshafen AG, Friedrichshafen (DE)

(21) Appl. No.: 18/837,504

(22) PCT Filed: Feb. 10, 2023
(86) PCT No.: PCT/EP2023/053281

§ 371 Date: Aug. 9, 2024

(30) Foreign Application Priority Data
Feb. 11, 2022 (DE) 10 2022 201 435.9

(51) Int. Cl. H03K 17/12

(52) U.S. Cl. CPC H03K 17/122; H03K 17/127

(57) ABSTRACT

A circuit assembly for a topological semiconductor switch in an inverter includes at least two power semiconductors and is subdivided into two groups of power semiconductors made of different semiconductor materials. The first group of power semiconductors is made up of power semiconductors with a wide bandgap. The size of the surface area occupied by the power semiconductors in the first group and/or their switching speed are configured for a load in a partial-load operation. The size of the surface area for the second group of power semiconductors is configured for loads in a full-load operation.

The present invention relates to the field of electric mobility.

Semiconductor transistors are used in many fields as electronic switches, also referred to as semiconductor switches. This is possible because a semiconductor switch can switch back and forth between two states. The first of these is when it is switched on. In this state, the semiconductor switch can conduct electricity, and behaves like a low resistor or a diode in the direction in which the electricity is conducted. In the other state, it is switched off. In this state, the semiconductor can absorb voltages of 400 V or 800 V.

A semiconductor switch switches between the two states quickly and efficiently. This switching on and off is the basis for many electronic circuits such as power supplies, converters, rectifiers, and inverters.

A typical method for increasing the performance of inverters is connecting power semiconductors in parallel. There are also numerous specially tailored semiconductor arrangements for inverters for improving efficiency. With the broad availability of silicon carbide MOSFETs (SiC-MOSFETs), the semiconductors in today's high-efficiency inverters are made purely from silicon carbide (SiC).

There are many reasons for reducing the SiC surface area on a chip, e.g. to save space and reduce costs. When SiC-MOSFETs are used, the surface area must be able to accommodate the freewheeling loads it is subjected to without malfunctioning. This requires a relatively large SiC surface area. The use of SiC-MOSFETs and Si-IGBTs (with antiparallel freewheeling diodes) has already been proposed.

Criteria relevant to the design so far have been the maximum phase current at the maximum intermediate circuit voltage, as well as the maximum cooling temperature (for cooling the components). The size of the surface area of the power semiconductor has so far been determined to ensure that the safe operating area (SOA) at the design-relevant operating point for the overall inverter system is not exceeded.

In the field of electric mobility, to comply with stricter fleet efficiency goals (established by lawmakers), it is necessary to increase the efficiency of the inverter through the use of novel semiconductor technologies, e.g. SiC-MOSFETs. The semiconductor surface area for normal, e.g. average, driving modes is oversized, because the design-relevant operating point is only rarely reached. The problem with this is that the semiconductor surface area in new technologies (wide-bandgap semiconductors, i.e. WBG semiconductors) that are more efficient (e.g. SiC or GaN), is more expensive than with conventional silicon. With conventional systems that have semiconductors made of a less expensive material (e.g. silicon), the size of this surface area can be tailored to the design-relevant operating point with safety margins, because the costs in relation to the semiconductor surface area are low compared to those for WBG materials. When WBG semiconductors are used in a conventional design, not only is space wasted, the costs are higher. It is therefore necessary to find an optimal balance between the best possible technologies and the lowest costs. The switching speed must be set to the design-relevant operating point. This means that the highest possible switching efficiency is not fully exploited during normal driving modes.

The object of the invention is to therefore improve the switching efficiency through an appropriate design of the power semiconductor in topological semiconductor switches for inverters in the automotive industry. This problem is solved with the invention by the features of the independent claims. Advantageous embodiments are the subject matter of the dependent claims.

To solve the problem, a circuit assembly for a topological semiconductor switch in an inverter is proposed. The topological semiconductor switch has at least two power semiconductors and is subdivided into two groups of power semiconductors made of different semiconductor materials. The first group is made of power semiconductors with a wide bandgap. The size of the surface area used by the first group of power semiconductors and/or their switching speed is based on a load during partial-load operation. The size of the surface area for the second group is based on the load during full-load operation.

In one embodiment, the first and second groups of power semiconductors are made of different types of semiconductors. In addition to using different materials, optimal semiconductor types can also be used for each application.

In one embodiment, the first group of power semiconductors are made of unipolar semiconductor elements. The semiconductor material can be SiC or GaN.

The second group of power semiconductors can be made of bipolar semiconductor elements. This second group can be made of silicon.

In one embodiment, the partial-load operation is the maximum load in a predefined driving cycle. This covers the load to the semiconductor during normal operation.

The driving cycle is advantageously an ARTEMIS driving cycle, WLTP driving cycle, or highway driving cycle, because these are standard methods for reproducing loads in conventional driving situations.

The size of the surface area used by the power semiconductors in the first group is determined in one embodiment such that it is as small as possible for the power semiconductor to be able to withstand the maximum possible load in a partial-load operation without exceeding its predefined load limits. In one embodiment, the size of the surface area used by the first group of power semiconductors is determined such that a predefined partial-load efficiency is obtained. The maximum partial-load efficiency is advantageously striven for. Depending on the requirements, there can therefore be different optimization goals.

In one embodiment, the full-load operation corresponds to a design-relevant maximum load for the power semiconductor.

The use of the circuit assembly in an inverter for an electronic module to control the electric drive in a vehicle with an electric drive is also proposed.

An electronic module for controlling an electric drive in a vehicle is also obtained, which has an inverter with the circuit arrangement described above. Furthermore, an electric drive for a vehicle that has the electronic module for controlling the electric drive and a corresponding vehicle with the electric drive are also obtained.

Other features and advantages of the invention can be derived from the following description of exemplary embodiments of the invention in reference to the drawings illustrating details of the invention, and from the claims. The individual features can be used in and of themselves or in various combinations forming variants of the invention.

Preferred embodiments of the invention shall be explained in greater detail below in reference to the drawings. Therein:

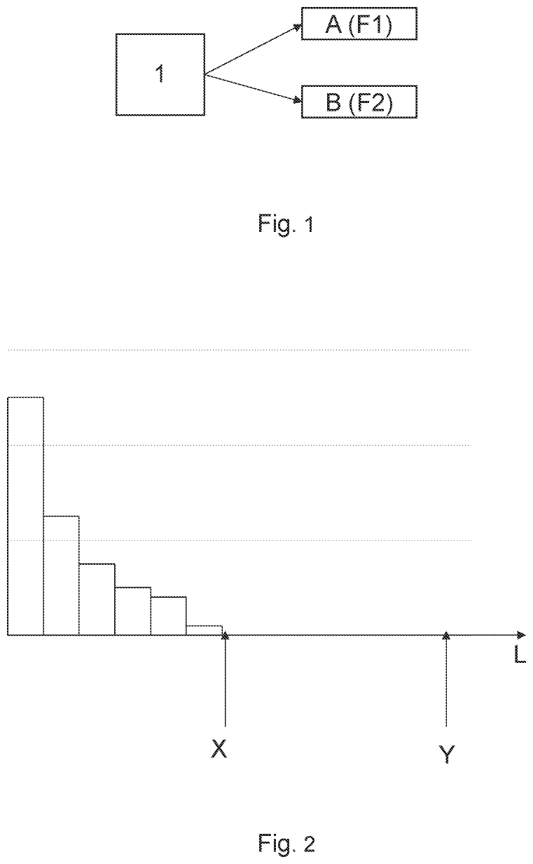

FIG. 1 shows the fundamental structure of the circuit assembly in an embodiment of the invention; and

FIG. 2 shows the fundamental load distribution for power semiconductors in an embodiment of the present invention.

Identical elements and functions have the same reference symbols in the following descriptions of the drawings.

Inverters, also referred to as power converters, require a power module or semiconductor package for converting the direct current from a battery into alternating current. The power module has topological switches with semiconductor transistors functioning as power transistors used to control the currents and for generating the alternating current. There are numerous designs for power transistors. These include MOSFETs (metal-oxide-semiconductor field-effect transistors) and IGBTs (insulated-gate bipolar transistors). The semiconductor material used therein can be silicon (Si), silicon carbide (SiC), gallium nitride (GaN) or any other semiconductor material. Materials with a wide bandgap are preferred.

The design of the semiconductor that is used is based on the selection of the type of semiconductor and the application, i.e. the goal that is to be achieved. Semiconductor transistors with silicon have a higher conductivity when used with bipolar elements with stronger currents, while semiconductor transistors with silicon carbide have this property when used with unipolar components with weaker currents. This allows the inverter to be optimized for specific purposes.

It is only necessary to ensure efficiency within defined driving cycles to reach efficiency goals. Operating points outside the driving cycles play a lesser role for efficiency goals, and can also be used with lower efficiency because they are rarely or never reached outside driving cycles in normal driving modes. Lower efficiency outside the driving cycles has very little negative impact on the travel range of the vehicle in normal driving modes.

Until now, it has always been assumed that the largest possible semiconductor surface would also result in the greatest efficiency. The following circuit assembly according to the invention refutes this view. A schematic circuit assembly is shown in FIG. 1, in which there are power semiconductors from a first group A, which occupy a surface area F1 therein, and power semiconductors in a second group B, which occupy a surface area F2 therein. They are controlled by a corresponding drive 1, which is not described in greater detail herein. FIG. 2 shows a schematic (histogram) illustration of the frequency (plotted on the y-axis, illustrated by vertical bars) of a load L (x-axis) to the power semiconductor. Point X is the maximum acceptable load in a driving cycle. Point Y is the design-relevant maximum load for the use of the power semiconductors that are used. It can be seen that the frequency of the load to the power semiconductor is practically zero at point Y. There is also practically no frequency in the load L at point X, toward which the load L decreases.

It can also be seen that a design of the power semiconductor in the first group A, which advantageously comprises semiconductors with a wide bandgap (WBG semiconductors), can be limited to a range within a driving cycle to reach high efficiencies. Loads are never, or only very rarely, expected outside the driving cycle, which means that a second group B can be used here. These are designed for loads L outside the driving cycle (without noticeably reducing the overall efficiency). This is also why the second group B can be made of the semiconductor materials such as silicon that have typically be used so far.

The invention makes use of a topological semiconductor switch with at least two power semiconductors, which are divided into two groups A and B, made of different semiconductor materials.

To comply with fleet efficiency goals and obtain a greater travel range with normal driving modes, the present operating points are covered by power semiconductors in the first group A. These have a semiconductor material with wider bandgaps, also referred to as WBG materials, e.g. SiC or GaN. These materials have a high inherent partial-load efficiency.

The size of the surface area F1 occupied by the power semiconductors in the first group A is based on the maximum load in partial-load operation (position X in FIG. 2), instead of a full-load operation (position Y in FIG. 2), as has been the case in the prior art. It can also be designed for a lower load than the design-relevant maximum load Y defined for every vehicle or type of vehicle based on its maximum performance. The partial-load operation is defined by a predefined driving cycle in which there is also a maximum load X that the power semiconductor must withstand. This maximum load X in the partial-load operation is significantly lower than the maximum load Y in the full-load operation, however.

Because the surface area F1 occupied by the power semiconductors in the first group A is tailored to partial-load operation, it can be significantly smaller and is therefore also significantly less expensive. It is surprising that the efficiency is not significantly lower that previously assumed, however, because by using a material such as SiC, some of the effects due to the smaller surface area have a lower impact on the losses than with a larger SiC surface area, and the sum of the losses over all of the effects that act on the efficiency is smaller than with a larger SiC surface area.

Because the switching speed is designed for partial-load operating points, specifically the maximum load X in partial-load operation, the switching speed of the WBG semiconductor, which represent the operating points in the driving cycle, no longer need to be set to the design-relevant operating point Y. This means that the switching efficiency in normal driving modes can be increased.

The surface area F1 occupied by the power semiconductors in the first group A is designed for operation up to a maximum load X to the power semiconductor, in which the SOA (safe operating area) is always to be maintained. This maximum load X can be defined by a driving cycle, e.g. an ARTEMIS driving cycle, WLTP driving cycle, or highway driving cycle, or some other standardized driving cycle. Because substantially all normal situations are covered by the stipulations of the driving cycles, the size of the surface area F1 occupied by the power semiconductors in the first group A can be tailored to such a driving cycle. This means that the surface area F1 can be as small as possible to be just large enough for the maximum load X in the driving cycle, therefore still complying with the SOA. This reduces costs for expensive WBG semiconductors, but may not result in the best possible (partial-load) efficiencies. For this reason, it may make sense to occupy a larger surface area. It can still be significantly smaller that if the power semiconductor were to be designed for full-load operation. The size of the surface area F1 can also depend on other effects, e.g. the size of the battery, and can be somewhere between the smallest possible surface area F1 while still complying with the SOA and a surface area F1 that results in maximum efficiency. The size of the surface area F1 can also be selected such that it is possible to obtain a symmetrical arrangement in the power module.

Outside the partial-load operation, the size of the surface area F2 must also be determined, and a design of the second group B must be obtained that satisfies the load in full-load operation, i.e. operation at the design-relevant maximum load Y for the circuit assembly. The second group B is advantageously not made of a WBG material, and is made instead of a conventional, and therefore less expensive, material such as silicon. Furthermore, the type of semiconductor used in the second group B is advantageously a bipolar semiconductor component such as an IGBT (with antiparallel freewheeling diodes).

The first and second group A, B are therefore always made of different semiconductor materials. They are also advantageously made of different types of semiconductors. The various types of semiconductors for the first group A are unipolar semiconductor elements such as MOSFETs, HEMTs, JFETs, etc., and the second group B are bipolar semiconductor elements such as IGBTs (with freewheeling diodes). A cascode circuit can also be used.

By using unipolar semiconductor elements made of a WBG material in the first group A, a power semiconductor can be obtained without a breaking voltage, which still exhibits good conductivity. This is the case in particular with an SiC-MOSFET.

The circuit assembly can be used in an inverter for an electronic module with which the electric drive in a vehicle with an electric drive is controlled.

The invention also results in an electronic module that has an inverter with the circuit assembly proposed herein, which can be used to control the electric drive in a vehicle, as well as an electric drive and a vehicle.

An electronic module in the framework of this invention is used to operate an electric drive in a vehicle, in particular an electric vehicle and/or hybrid vehicle. The electronic module contains a DC/AC inverter, which has the inverter structure, or a part thereof, described herein. The electronic module can also contain an AC/DC rectifier, a DC/DC converter, a transformer, and/or some other electric converter, or part of such a converter, or a part thereof. In particular, the electronic module supplies electricity to an electric machine, e.g. an electric motor and/or generator. A DC/AC inverter is preferably used to generate a multi-phase alternating current from a direct current generated by a DC voltage from an energy source, e.g. a battery.

Inverters for electric drives in vehicles, in particular passenger automobiles and utility vehicles, as well as busses, are designed for high voltage, and are classified for 650 V to 1,200 V, or a voltage classification for battery voltage of ca. 400 V to 800 V, and in some cases as low as 200 V.

### List of Reference Symbols

1 control
A, B power semiconductor groups
F1, F2 surface area of the power semiconductors in each group
L load to the power semiconductors
X maximum load in a driving cycle
Y design-relevant maximum load

1. A circuit assembly for a topological semiconductor switch in an inverter, wherein the topological semiconductor switch comprises:
at least two power semiconductors subdivided into a first group of power semiconductors and a second group of power semiconductors, wherein the first group and the second group are made of different semiconductor materials,
wherein the first group of power semiconductors is made up of power semiconductors with a wide bandgap, and wherein a size of a surface area occupied by the power semiconductors in the first group and/or their switching speed are configured for a load in a partial-load operation, and
wherein a size of a surface area occupied by the power semiconductors in the second group is configured for a load in a full-load operation.

2. The circuit assembly according to claim 1, wherein the first and second groups of power semiconductors are made of different types of semiconductors.

3. The circuit assembly according to claim 1, wherein the first group of power semiconductors are made up of unipolar semiconductor components, and/or the semiconductor material is SiC or GaN.

4. The circuit assembly according to claim 1, wherein the second group of power semiconductors are made up of bipolar semiconductor components and/or made of semiconductor material silicon.

5. The circuit assembly according to claim 1, wherein the partial-load operation corresponds to a maximum load to the respective power semiconductor in a predefined driving cycle.

6. The circuit assembly according to claim 5, wherein the predefined driving cycle is an ARTEMIS driving cycle, a Worldwide harmonized Light vehicles Test Procedure (WLTP) driving cycle, or a highway driving cycle.

7. The circuit assembly according to claim 5, wherein the size of the surface area occupied by the power semiconductors in the first group is determined such that:
the surface area is as small as possible to still be able to withstand the maximum possible load in the partial-load operation, without exceeding its predefined load limits; or
the surface area is selected such that a predefined partial-load efficiency is obtained.

8. The circuit assembly according to claim 7, wherein the surface area is selected such that a maximum partial-load efficiency is obtained.

9. The circuit assembly according to claim 1, wherein the full-load operation corresponds to a design-relevant maximum load for the respective power semiconductor.

10. An inverter for an electronic module for controlling an electric drive in an electric vehicle, comprising:
the circuit assembly according to claim 1.

11. An electronic module for controlling an electric drive in a vehicle, comprising:
an inverter with the circuit assembly according to claim 1.

12. An electric drive for a vehicle, comprising:
the electronic module according to claim 11.

13. A vehicle comprising:
the electric drive according to claim 12.

14. The circuit assembly according to claim 2, wherein the first group of power semiconductors are made up of unipolar semiconductor components, and/or the semiconductor material is SiC or GaN.

15. The circuit assembly according to claim 14, wherein the second group of power semiconductors are made up of bipolar semiconductor components and/or made of semiconductor material silicon.

16. The circuit assembly according to claim 2, wherein the second group of power semiconductors are made up of bipolar semiconductor components and/or made of semiconductor material silicon.

17. The circuit assembly according to claim 3, wherein the second group of power semiconductors are made up of bipolar semiconductor components and/or made of semiconductor material silicon.
